(19) United States
(12) Patent Application Publication
(10) Pub. No.: US 2014/0241068 A1
(43) Pub. Date: Aug. 28, 2014

(54) NON-VOLATILE SEMICONDUCTOR STORAGE DEVICE

(71) Applicant: Kabushiki Kaisha Toshiba, Tokyo (JP)

(72) Inventors: Takashi IZUMIDA, Yokohama-shi (JP); Masaki KONDO, Kawasaki-shi (JP)

(21) Appl. No.: 13/935,761

(22) Filed: Jul. 5, 2013

(30) Foreign Application Priority Data
Feb. 26, 2013 (JP) 2013-035876

(51) Int. Cl. G11C 16/34

(52) U.S. Cl. CPC G11C 16/3459
USPC 365/185.22

(57) ABSTRACT

In one embodiment, a non-volatile semiconductor storage device includes a memory cell array in which a plurality of non-volatile memory cells is aligned, and a control unit which repeats a write operation of applying a write voltage to a selected memory cell, a verify operation of checking whether or not data write is completed, and a step-up operation of stepping up the write voltage by an amount of a predetermined step-up voltage when the data write is not completed. Upon the write operation, the control unit applies a first transfer voltage, a voltage value of which is lower than the write voltage, to a first unselected memory cell which is adjacent to the selected memory cell, and applies a second transfer voltage, a voltage value of which is lower than the first transfer voltage, to a second unselected memory cell which is not adjacent to the selected memory cell.

### CROSS REFERENCE TO RELATED APPLICATION

This application is based upon and claims benefit of priority from the Japanese Patent Application No. 2013-35876, filed on Feb. 26, 2013, the entire contents of which are incorporated herein by reference.

### FIELD

Embodiments described herein relate generally to a non-volatile semiconductor storage device.

### BACKGROUND

A NAND type flash memory includes a memory array formed by aligning NAND strings obtained by connecting a plurality of memory cells in series, and is suitable for providing a greater capacity. Further, providing a still larger volume by means of a multivalued memory scheme which stores data of two bits or more per memory cell is proposed.

Upon data write of a NAND type flash memory, a write voltage Vpgm is applied to a control gate (word line) of a selected memory cell being a writing target. Further, a write pass voltage Vpass (Vpass<Vpgm) which is a transfer voltage to turn on a memory cell is applied to a control gate of an unselected memory cell. Until a desired threshold voltage is obtained, a write cycle including a write operation (program operation) and a subsequent verify operation is repeated. Further, to precisely control a threshold voltage distribution, the write voltage Vpgm is stepped up by ΔVpgm at every write cycle.

When the write voltage Vpgm is applied to the selected memory cell, a floating gate potential Vfg increases by ΔVpgm×Cr. Meanwhile, Cr represents a coupling ratio. When a tunnel current flows from a substrate to the floating gate, a floating gate potential Vfg decreases by ΔVfg. ΔVfg/Cr corresponds to a fluctuation amount ΔVth of a threshold voltage. Hence, ΔVth/ΔVpgm is fixed. Conventionally, a variation range of a threshold voltage distribution upon data write is controlled using ΔVpgm. Such control is based on a precondition that the coupling ratios Cr upon writing and upon reading are the same. When the coupling ratios Cr upon writing and upon reading differ due to thinning of the floating gate or complication of a structure following miniaturization, ΔVth/ΔVpgm can no more be fixed. In addition, ΔVth/ΔVpgm also changes depending on voltage conditions, and there is a problem that a threshold voltage distribution after writing deteriorates.

Further, the amount of electrons to be written is obtained by: time×tunnel probability. Hence, when one write cycle is finished, an insufficiently written state is provided in some cases. There is a problem that, when writing is performed in this insufficiently written state in a next write cycle, a threshold voltage distribution deteriorates.

### BRIEF DESCRIPTION OF THE DRAWINGS

FIG. 1 is a view illustrating a schematic configuration of a non-volatile semiconductor storage device according to a first embodiment of the present invention;

FIG. 2 is a view illustrating a relationship between data stored in a memory cell and a threshold voltage; FIG. 3 is a view explaining a voltage to be applied to a NAND cell unit at a write operation;

FIG. 4 is a view illustrating how a write voltage steps up;

FIG. 5 is a graph illustrating changes of a transfer voltage according to a first embodiment;

FIG. 6 is a graph illustrating an example of a relationship between a write voltage and ΔVth/ΔVpgm;

FIG. 7 is a graph illustrating changes of a transfer voltage according to a second embodiment;

FIG. 8 is a graph illustrating changes of a transfer voltage according to a third embodiment;

FIG. 9 is a graph illustrating changes of a transfer voltage according to a fourth embodiment;

FIG. 10 is a graph illustrating changes of a transfer voltage according to a fifth embodiment; and

FIG. 11 is a graph illustrating changes of a transfer voltage according to a sixth embodiment.

### DETAILED DESCRIPTION

In one embodiment, a non-volatile semiconductor storage device includes a memory cell array in which a plurality of non-volatile memory cells is aligned, and a control unit which repeats a write operation of applying a write voltage to a selected memory cell, a verify operation of checking whether or not data write is completed, and a step-up operation of stepping up the write voltage by an amount of a predetermined step-up voltage when the data write is not completed. Upon the write operation, the control unit applies a first transfer voltage, a voltage value of which is lower than the write voltage, to a first unselected memory cell which is adjacent to the selected memory cell, and applies a second transfer voltage, a voltage value of which is lower than the first transfer voltage, to a second unselected memory cell which is not adjacent to the selected memory cell.

Embodiments will now be explained with reference to the accompanying drawings.

### First Embodiment

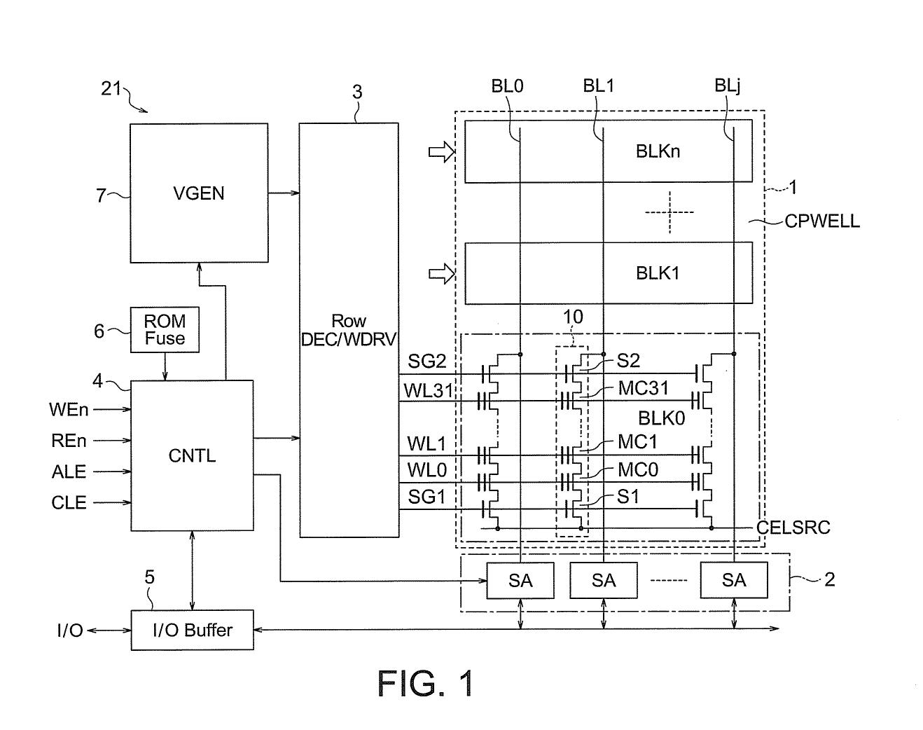

FIG. 1 is a view illustrating a schematic configuration of a non-volatile semiconductor storage device according to a first embodiment of the present invention. As illustrated in FIG. 1, a NAND type flash memory 21 has a memory cell array 1, a sense amplifier circuit 2, a row decoder 3, a controller 4, an input/output buffer 5, a ROM fuse 6 and a voltage generation circuit 7. The controller 4 configures a control unit for the memory cell array 1.

The memory cell array 1 is formed by aligning NAND cell units (NAND strings) 10 in a matrix pattern. One NAND cell unit 10 is formed with a plurality of memory cells MC (MC0, MC1, . . . and MC31) connected in series, and selection gate transistors S1 and S2 connected to both ends of the plurality of memory cells.

Although not illustrated, one memory cell MC can adopt a known laminated gate type structure. The memory cell MC has a floating gate which is a charge accumulation layer formed on a gate insulation film (tunnel insulation film) formed between a drain and a source, and a control gate which is formed on the floating gate across an inter-gate insulation film. The control gates of the memory cells MC in the cell unit 10 are respectively connected to different word lines (WL₀, WL₁, . . . , and WL₃₁).

A source of the selection gate transistor S1 is connected to a common source line CELSRC, and a drain of the selection gate transistor S2 is connected to a bit line BL. Gate electrodes of the selection gate transistors S1 and S2 are connected to the selection gate lines SG1 and SG2 parallel to the word lines WL. A set of the memory cells MC which share one word line WL configures one page. When the memory cell MC stores multivalued data or when an even-numbered bit line and an odd-numbered bit line are switched and controlled, a set of the memory cells MC which share one word line WL configures a plurality of pages equal to or more than twopages.

As illustrated in FIG. 1, a set of a plurality of NAND cell units 10 which share the word lines WL and the selection gate lines SG1 and SG2 configures a block BLK which is a data erase unit. In the memory cell array 1, a plurality of blocks BLK (BLK0, BLK1, . . . and BLKn) are formed in a bit line BL direction. The memory cell array 1 including the plurality of these blocks is formed in one cell well of a silicon substrate.

The bit lines BL of the memory cell array 1 are connected with the sense amplifier circuit 2 which includes a plurality of sense amplifiers SA. The sense amplifier SA configures a page buffer which senses read data and holds write data. The sense amplifier circuit 2 has a column selection gate. The row decoder (including a word line driver WDRV) 3 selects and drives the word lines WL and the selection gate lines SG1 and SG2

The data input/output buffer 5 sends and receives data between the sense amplifier circuit 2 and an external input/output terminal, and, in addition, receives command data or address data. The controller 4 receives external control signals such as a write enable signal WEn, a read enable signal REn, an address latch enable signal ALE and a command latch enable signal CLE, and controls an overall memory operation.

More specifically, the controller 4 includes a command interface and an address hold/transfer circuit, and determines whether supplied data is write data or address data. According to this decision result, the write data is transferred to the sense amplifier circuit 2, and the address data is transferred to the row decoder 3 or the sense amplifier circuit 2. Further, based on external control signals, the controller 4 performs sequence control for read, write and erase operations, and controls an applied voltage.

The voltage generation circuit 7 generates a desired pulse voltage based on a control signal from the controller 4. The voltage generation circuit 7 generates various voltages required for a write operation, an erase operation and a read operation.

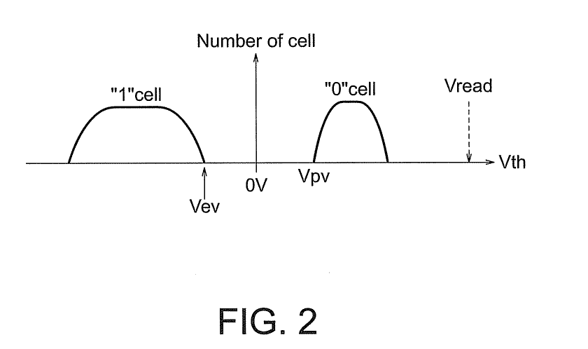

FIG. 2 is a view illustrating a relationship between data stored in the memory cell MC and a threshold voltage. In a case of storing binary data, when the memory cell MC has a negative threshold voltage, the memory cell MC is defined as a “1” cell which holds logical “1” data. When the memory cell MC has a positive threshold voltage, the memory cell MC is defined as a “0” cell which holds logical “0” data. An operation of placing the memory cell MC in a “1” data state is referred to as the erase operation, and an operation of placing the memory cell MC in a “0” state is referred to as the write operation.

### [Erase Operation]

The NAND type flash memory performs a data delete operation normally in block units. In the data erase operation, an erase pulse voltage Vera (about 10 to 30 V) is applied to the cell well, and 0 V is applied to all word lines WL in the selected block. A charge of a floating gate electrode of each memory cell MC is pulled toward the cell well by a FN tunnel current, and the threshold voltage of the memory cell MC decreases. In this step, the selection gate lines SG1 and SG2 are placed in floating states to prevent gate oxide films of the selection gate transistors S1 and S2 from being broken.

Further, the bit lines BL and the source line CELSRC are also placed in the floating states. In addition, according to a result of an erase verify operation after the erase operation, the erase operation is executed again. When the erase operation is performed again, the erase pulse voltage Vera is stepped up by a predetermined voltage at a time, and the erase operation is executed using the stepped up voltage.

### [Write Operation]

FIG. 3 is a view explaining a voltage to be applied to the NAND cell unit at the write operation. The write operation is executed in page units. During the write operation, the write voltage Vpgm is applied to a selected word line (WLₙ) in the selected block. n represents an integer satisfying 0≦n ≦31.

Further, a first transfer voltage Vpassl is applied to word lines (WLₙ₋ₗ and WLₙ₊₁) which are adjacent to the selected word line, and a second transfer voltage Vpass2 is applied to other unselected word lines (WL₀, WL₁, . . . WLₙ₋₂, WLₙ₊₂, . . . and WL₃₁). The first transfer voltage Vpassl and the second transfer voltage Vpass2 are lower than the write voltage Vpgm. The first transfer voltage Vpassl and the second transfer voltage Vpass2 will be described below.

A voltage Vdd is applied to the selection gate line SG2.

Prior to this write operation, the bit lines BL and the NAND cell units 10 are pre-charged according to write data. More specifically, to write “0” data, 0 V is applied to the bit lines BL from the sense amplifier circuit 2. This bit line voltage is transferred to a channel of the memory cell MC connected to the selected word line WLₙ through the selection gate transistor S2 and the unselected memory cells MC. Hence, a charge is injected to the floating gate electrode from the channel of the selected memory cell MC under the above write operation conditions, and the threshold voltage of the memory cell MC shifts to a positive side (“0” cell).

When “1” is written (that is, when writing is forbidden and “0” data is not written in the selected memory cell MC), the voltage Vdd is applied to the bit lines BL. This bit line voltage Vdd decreases by the threshold voltage of the selection gate transistor S2 and is transferred to a channel of a NAND cell unit, and then the channel is placed in a floating state. By this means, when the above write voltage Vpgm, the first transfer voltage Vpass1 and the second transfer voltage Vpass2 are applied, a channel voltage is stepped up by capacitive coupling, and the charge is not injected to the floating gate. Hence, the memory cell MC holds “1” data.

Similar to the erase operation, the write operation is executed again according to a result of the write verify operation described below. When the write operation is performed again, the write pulse voltage Vpgm is stepped up by a voltage ΔVpgm at a time, and the write operation is executed using the stepped up voltage Vpgm+ΔVpgm. Meanwhile, a write pulse voltage to be applied first is a voltage Vpgm0.

### [Read Operation]

The data read operation is directed to applying a read voltage 0 V to the word line WL (selected word line WLₙ) connected with the selected memory cell MC in the NAND cell unit 10. Further, a read pass voltage Vread is applied to the word lines WL (unselected word lines WL₀, WL₁, . . . , WLₙ₋₁, WLₙ₊₁, . . . and WL₃₁) connected with the unselected memory cells MC. In this case, whether or not a current flows in the NAND cell unit 10 is detected by the sense amplifier circuit 2 to determine data.

### [Write Verify Operation]

In the data read, a margin which guarantees data reliability is required between a set threshold voltage state and the read voltage 0 V. Hence, the data erase operation and the write operation need to be controlled such that a lower limit value Vpv of a threshold voltage distribution of “0” data and an upper limit value Vev of a threshold voltage distribution of “1” data have an adequate margin in relation to the voltage 0 V (see FIG. 2).

Hence, after the write voltage Vpgm is applied in the above write operation, a verify read (write verify) operation is performed for checking whether or not the threshold voltage of the selected memory cell MC is the lower limit value Vpv or more. In a case of the erase operation, after the above operation of applying an erase pulse voltage is performed, a verify read (erase verify) operation is performed for checking whether or not the threshold voltage of an erase memory cell is the upper limit value Vev of the distribution of the threshold voltage or less.

The write verify operation is substantially the same operation as the above read operation. That is, the read pass voltage Vread is applied to the word lines WL(unselected word lines WL₀, WL₁, . . . WL_{n -1}, WLₙ₊₁, . . . and WL₃₁) connected with the unselected memory cells MC, and the selection gate lines SG1 and SG2. Further, the voltage Vdd is applied to the bit lines BL, and 0 V is applied to the common source line CELSRC. Meanwhile, a write verity voltage Vpv is applied to the word line WL (selected word line WLₙ ) connected with the selected memory cell MC. In this case, whether or not a current flows in the NAND cell unit 10 is detected by the sense amplifier circuit 2 to determine data.

When the selected memory cell MC is in a data “0” state as a result of writing, even performing the above write verify operation does not cause a flow of a current in the NAND cell unit 10. Meanwhile, when the threshold voltage of the selected memory cell MC does not reach a distribution of the data “0” state, a current flows in the NAND cell unit 10. When it is detected that the selected memory cell MC is in a data “0” state as a result of writing, writing in the selected memory cell MC is sufficiently performed, and the write operation is finished. If the selected memory cell is not in the data “0” state as a result of writing, the write operation is performed again for the selected memory cell MC.

### [Step-Up Operation]

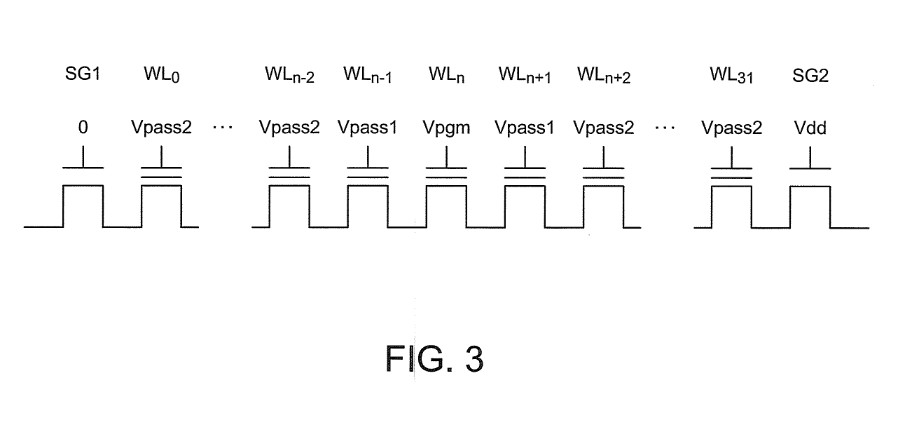

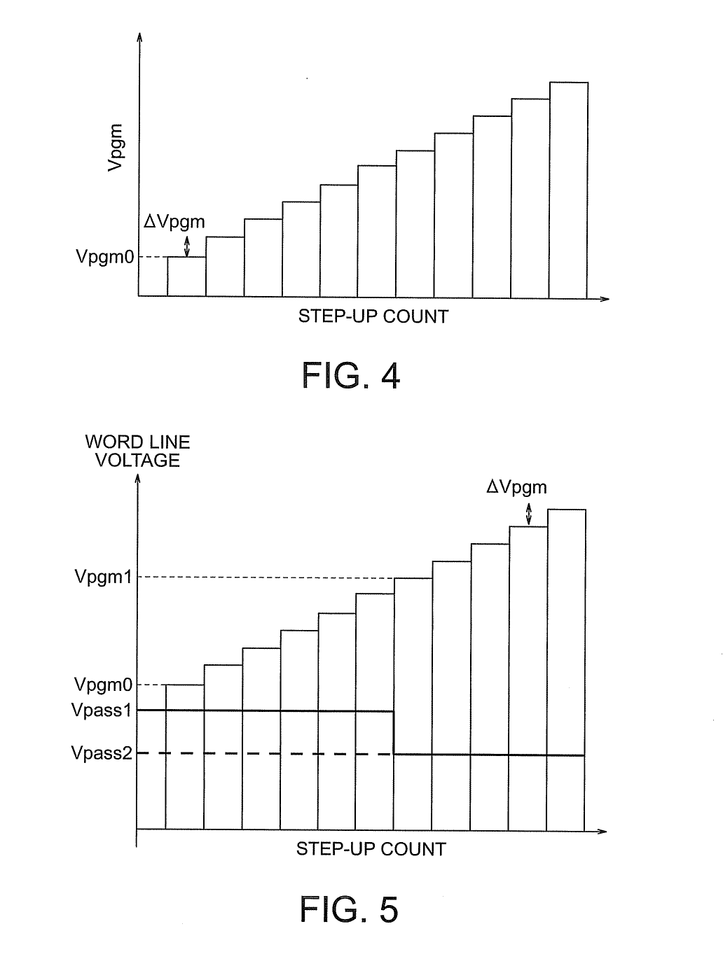

FIG. 4 is a view illustrating how the write voltage Vpgm is stepped up when the write operation is performed again after the write verify operation. When the write operation is performed again, the write voltage Vpgm is set to a voltage (Vpgm0+ΔVpgm), which is greater than an initial value Vpgm0, by a step-up value ΔVpgm (>0). When there is the memor y cell MC in which writing is insufficient even after a reset large write pulse voltage Vpgm=Vpgm0+ΔVpgm is applied, a step-up operation of further increasing a pulse voltage by the step-up value ΔVpgm is performed (Vpgm=Vpgm0+2ΔVpgm). Subsequently, the write operation, the write verify operation and the step-up operation are repeated until the data write is completed. As the repetition count increases, the write pulse voltage Vpgm is stepped up by ΔVpgm at a time. In addition, a step-up range is not limited to the one with a uniform increase of ΔVpgm at a time, and the write pulse voltage Vpgm only needs to take a value which is higher than a previous write pulse voltage.

### [First Transfer Voltage Vpassl and Second Transfer Voltage Vpass2]

As described above, the write voltage Vpgm is stepped up by the voltage ΔVpgm at a time according to a result of the write verify operation. Meanwhile, the first transfer voltage Vpassl and the second transfer voltage Vpass2 can be controlled as described below.

FIG. 5 is a graph illustrating transitions of the write voltage Vpgm, the first transfer voltage Vpass1 and the second transfer voltage Vpass2. A bar graph indicates the write voltage Vpgm. Further, a solid line indicates the first transfer voltage Vpass1, and a broken line indicates the second transfer voltage Vpass2.

First, the write voltage Vpgm is set to the voltage Vpgm0, and the write operation is started. In this case, the first transfer voltage Vpass1 has a value higher than the second transfer voltage Vpass2 and lower than the write voltage Vpgm0. The second transfer voltage Vpass2 is fixed.

When the number of times to apply the write voltage Vpgm reaches a predetermined number of times, the first transfer voltage Vpass1 is fixed to a value higher than the second transfer voltage Vpass2 until the write voltage Vpgm reaches Vpgm1. Further, after the number of times to apply the write voltage Vpgm reaches a predetermined number of times, the first transfer voltage Vpass1 is decreased to a value equal to the second transfer voltage Vpass2 when the write voltage Vpgm reaches Vpgm1.

Following depletion of the floating gate, a potential change amount ΔVfg of the floating gate corresponding to ΔVpgm fluctuates and, as a result, ΔVth (a fluctuation amount of the threshold voltage)/ΔVpgm fluctuates. In the present embodiment, by making the first transfer voltage Vpass1 to be applied to word lines (WLₙ₋₁and WLₙ₊₁) which are adjacent to a selected word line higher than the second transfer voltage Vpass2 to be applied to other unselected word lines (WL₀, WL₁, . . . , WLₙ₌₂, WLₙ₊₂, . . . and WL₃₁), capacitive coupling of the adjacent word lines (WLₙ₋₁ and WLₙ₊₁) and a floating gate of the selected memory cell can suppress fluctuation of ΔVfg due to an influence of depletion and can suppress fluctuation of ΔVth/ΔVpgm.

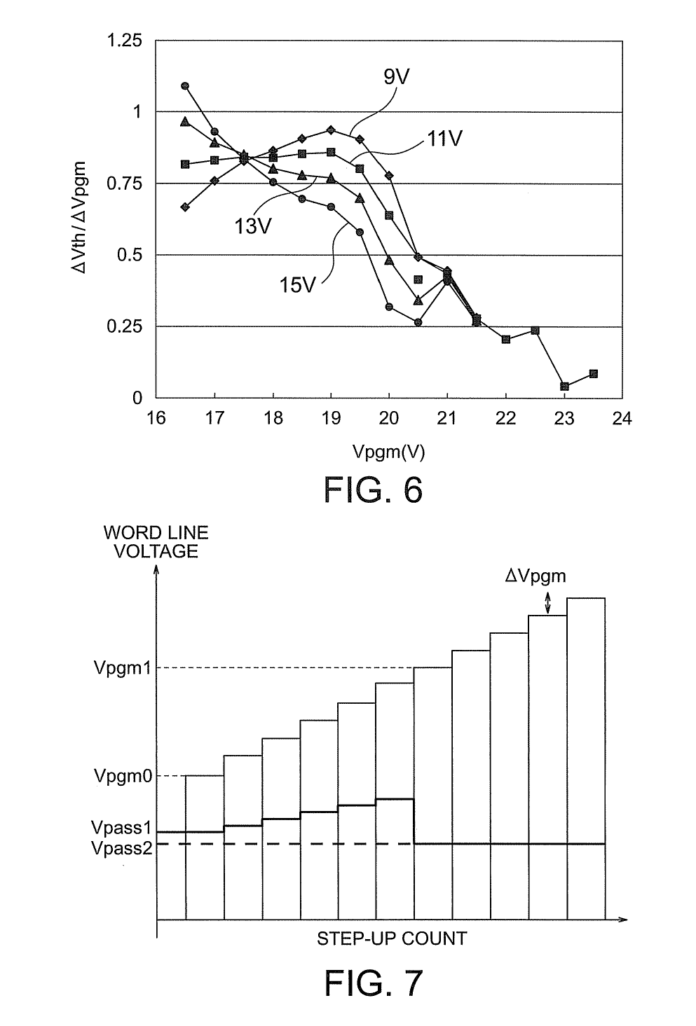

FIG. 6 is a graph illustrating an example of a relationship between the write voltage Vpgm and ΔVth/ΔVpgm when the first transfer voltage Vpass1 is set to 9 V, 11 V, 13 V and 15 V. The second transfer voltage Vpass2 is set to 9 V.

When the first transfer voltage Vpass1 and the second transfer voltage Vpass2 are equal (Vpass1=Vpass2=9 V), ΔVth/ΔVpgm steps up following a step-up of the write voltage Vpgm until the write voltage Vpgm reaches about 19 V, and a distribution range of the threshold voltage Vth is increased.

By contrast with this, when the first transfer voltage Vpass1 is made higher than the second transfer voltage Vpass2, ΔVth/ΔVpgm is substantially fixed or decreases following a step-up of the write voltage Vpgm in a range in which the write voltage Vpgm becomes about 19 V. Consequently, it is possible to prevent the distribution range of the threshold voltage Vth from becoming large.

Further, by making the first transfer voltage Vpass1 to be applied to word lines which are adjacent to a selected word line higher than the second transfer voltage Vpass2 to be applied to the other unselected word lines, it is possible to increase a potential of the floating gate of the selected memory cell and increase a probability that writing in the floating gate is sufficiently performed. By placing the floating gate in a sufficiently written state and decreasing the first transfer voltage Vpass1 to a value equal to the second transfer voltage Vpass2 at a point of time when the write voltage Vpgm becomes equal to the predetermined voltage Vpgm1, it is possible to prevent the threshold voltage from rapidly stepping up following rapid writing in the floating gate.

Thus, according to the present embodiment, it is possible to prevent variation in a threshold voltage distribution after writing.

In addition, voltage values of the write voltage Vpgm, the first transfer voltage Vpass1 and the second transfer voltage Vpass2 can be controlled by the voltage generation circuit 7. By, for example, changing the number of booster circuits in the voltage generation circuit 7, it is possible to control the write voltage Vpgm, the first transfer voltage Vpass1 and the second transfer voltage Vpass2.

Although an example has been described according to the embodiment where the number of word lines WL is 32, the number of word lines WL is not limited to this, and may be other values such as 64 or 128.

### Second Embodiment

Although a first transfer voltage Vpass1 is fixed to a value higher than a second transfer voltage Vpass2 until a write voltage Vpgm becomes equal to Vpgm1 in the first embodiment, as illustrated in FIG. 7, the first transfer voltage Vpass1 may be gradually stepped up in a range in which the first transfer voltage Vpass1 is higher than the second transfer voltage Vpass2 and is lower than the write voltage Vpgm0 until the write voltage Vpgm becomes equal to Vpgm1. The first transfer voltage Vpass1 upon start of writing is made lower than the first transfer voltage Vpass1 upon start of writing in the first embodiment.

By controlling the first transfer voltage Vpass1 in this way, a difference between the write voltage Vpgm and the first transfer voltage Vpass1 becomes more significant compared to the first embodiment and a tunneling probability in a selected memory cell increases. Consequently, it is possible to place a floating gate in a sufficiently written state.

### Third Embodiment

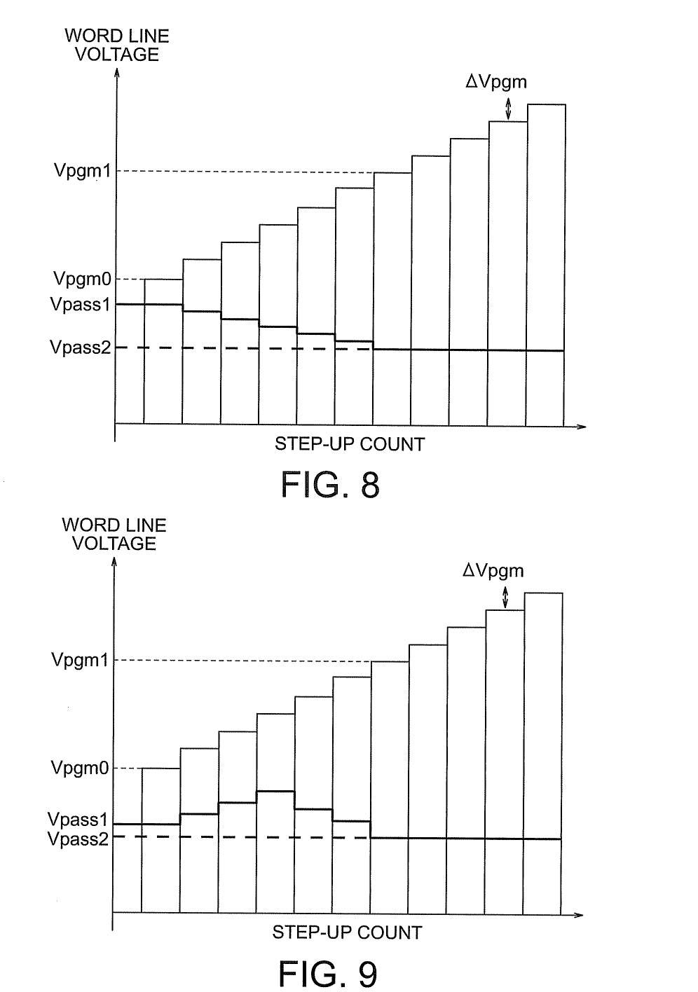

As illustrated in FIG. 8, a first transfer voltage Vpass1 may be gradually stepped down within a range in which the first transfer voltage Vpass1 is higher than a second transfer voltage Vpass2 and is lower than a write voltage Vpgm0 until the write voltage Vpgm becomes equal to Vpgm1. For example, the first transfer voltage Vpass1 upon start of writing is substantially the same as the first transfer voltage Vpass1 upon start of writing in the first embodiment.

By controlling the first transfer voltage Vpass‘in this way, it is possible to further suppress fluctuation of ΔVth/ΔVpgm. Consequently, it is possible to further prevent variation in a threshold voltage distribution after writing.

### Fourth Embodiment

As illustrated in FIG. 9, a first transfer voltage Vpass1 may be gradually stepped up within a range in which the first transfer voltage Vpass1 is higher than a second transfer voltage Vpass2 and is lower than a write voltage Vpgm0 until a write voltage Vpgm becomes equal to Vpgm1, and then be gradually stepped down.

By controlling the first transfer voltage Vpass1 in this way, a tunneling probability in a selected memory cell increases compared to the first embodiment and, consequently, it is possible to place a floating gate in a sufficiently written state. It is also possible to further suppress fluctuation of ΔVth/ΔVpgm, and further prevent variation in a threshold voltage distribution after writing.

### Fifth Embodiment

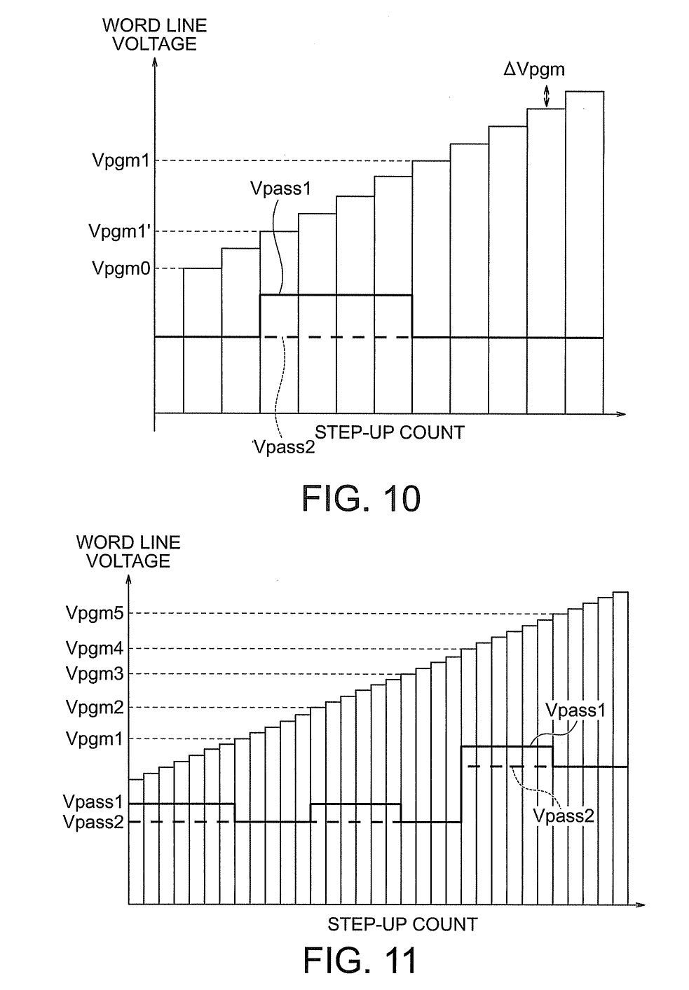

Although a first transfer voltage Vpass1 is fixed to a value higher than a second transfer voltage Vpass2 until a write voltage Vpgm becomes equal to Vpgm1 in the first embodiment, as illustrated in FIG. 10, the first transfer voltage Vpass1 may be set to the same value as that of the second transfer voltage Vpass2 until the write voltage Vpgm becomes equal to Vpgm1′, and set to a value higher than the second transfer voltage Vpass2 and lower than a voltage Vpgm0 until the write voltage Vpgm becomes equal to Vpgm1 after the write voltage Vpgm becomes equal to Vpgm1′.

By controlling the first transfer voltage Vpass1 in this way, it is also possible to provide the same effect as that in the first embodiment.

### Sixth Embodiment

As illustrated in FIG. 11, when a write voltage Vpgm becomes equal to Vpgm1 and the write voltage Vpgm becomes equal to Vpgm2 (>Vpgm1) after a first transfer voltage Vpass1 is stepped down to the same value as that of a second transfer voltage Vpass2, the first transfer voltage Vpass1 may be stepped up again. In this case, when the write voltage Vpgm becomes equal to Vpgm3 (>Vpgm2), the first transfer voltage Vpass1 is stepped down to the same value as that of the second transfer voltage Vpass2.

Further, as illustrated in FIG. 11, when the write voltage Vpgm becomes equal to Vpgm4 (>Vpgm3), the first transfer voltage Vpass1 and the second transfer voltage Vpass2 may be stepped up. Subsequently, when the write voltage Vpgm becomes equal to Vpgm5 (>Vpgm4), the first transfer voltage Vpass1 is stepped down to the same value as that of the second transfer voltage Vpass2. In this case, the first transfer voltage Vpass1 and the second transfer voltage Vpass2 may be greater than the write voltage Vpgm0 upon start of writing.

Even when a write cycle is repeated by controlling the first transfer voltage Vpass1 in this way and the write voltage Vpgm becomes higher, it is possible to suppress fluctuation of ΔVth/ΔVpgm, and suppress variation in a threshold voltage distribution by increasing a probability that writing in a floating gate of a selected memory cell is sufficiently performed.

Although, when the first transfer voltage Vpass1 is higher than the second transfer voltage Vpass2, the first transfer voltage Vpass1 is fixed in the sixth embodiment, the first transfer voltage Vpass1 may be stepped up or stepped down following a step-up of the write voltage Vpgm as in the second to fourth embodiments.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A non-volatile semiconductor storage device comprising:
a memory cell array in which a plurality of non-volatile memory cells is aligned; and
a control unit which repeats a write operation of applying a write voltage to a selected memory cell, a verify operation of checking whether or not data write is completed, and a step-up operation of stepping up the write voltage by an amount of a predetermined step-up voltage when the data write is not completed,
wherein, upon the write operation, the control unit applies a first transfer voltage, a voltage value of which is lower than the write voltage, to a first unselected memory cell which is adjacent to the selected memory cell, and applies a second transfer voltage, a voltage value of which is lower than the first transfer voltage, to a second unselected memory cell which is not adjacent to the selected memory cell.

2. The non-volatile semiconductor storage device according to claim 1, wherein, when the write voltage reaches a first predetermined value, the control unit steps down the first transfer voltage to a same voltage value as the second transfer voltage.

3. The non-volatile semiconductor storage device according to claim 2, wherein the voltage value of the second transfer voltage is fixed.

4. The non-volatile semiconductor storage device according to claim 2, wherein the control unit steps up the first transfer voltage following the step-up of the write voltage until the write voltage reaches the first predetermined value.

5. The non-volatile semiconductor storage device according to claim 2, wherein the control unit steps down the first transfer voltage following the step-up of the write voltage until the write voltage reaches the first predetermined value.

6. The non-volatile semiconductor storage device according to claim 2, wherein the control unit
steps up the first transfer voltage following the step-up of the write voltage until the write voltage reaches a second predetermined value which is lower than the first predetermined value, and
steps down the first transfer voltage following the step-up of the write voltage until the write voltage reaches the first predetermined value after the write voltage reaches the second predetermined value.

7. The non-volatile semiconductor storage device according to claim 2, wherein the control unit
sets the first transfer voltage to a same value as that of the second transfer voltage until the write voltage reaches a second predetermined value which is lower than the first predetermined value, and
steps up the first transfer voltage when the write voltage reaches the second predetermined value.

8. The non-volatile semiconductor storage device according to claim 2, wherein the control unit steps up the first transfer voltage when the write voltage reaches a second predetermined value which is higher than the first predetermined value, and steps down the first transfer voltage to a same voltage value as that of the second transfer voltage when the write voltage reaches a third predetermined value which is higher than the second predetermined value.

9. The non-volatile semiconductor storage device according to claim 8, wherein the control unit steps up the first transfer voltage and the second transfer voltage when the write voltage reaches a fourth predetermined value which is lower than the third predetermined value.

10. The non-volatile semiconductor storage device according to claim 9, wherein the control unit steps up the first transfer voltage and the second transfer voltage to voltage values which are higher than a write voltage at an initial write operation when the write voltage reaches the fourth predetermined value.
